(19) United States
(12) Patent Application Publication
(10) Pub. No.: US 2010/0238299 A1
(43) Pub. Date: Sep. 23, 2010

(54) Display Characteristic Feedback Loop

(75) Inventors: William DUNN, Alpharetta, GA (US); David Williams, Canton, GA (US)

Correspondence Address: STANDLEY LAW GROUP LLP, 6300 Riverside Drive, Dublin, OH, 43017, US

(73) Assignee: MANUFACTURING RESOURCES INTERNATIONAL, Alpharetta, GA (US)

(21) Appl. No.: 12/706,594

(22) Filed: Feb. 16, 2010

Related U.S. Application Data
(60) Provisional application No. 61/152,876, filed on Feb. 16, 2009.

(51) Int. Cl. H04N 17/02; G01R 31/44

(52) U.S. Cl. 348/189; 324/414; 348/E17.004

(57) ABSTRACT

A system and method for remotely monitoring and transmitting optical data for an electronic display to a user. A color light sensor is placed in front of the viewable area of an electronic display and is used to measure various optical properties to determine if the display is functioning properly. The user may be notified when a display is malfunctioning. The display may store optical data locally for later retrieval by the user. The user may access the optical data through a network connection with the display. One or more displays may be placed adjacent to one another and their optical properties may be measured and balanced so that the displays match one another or can be used as a harmonious array. A watermark can be used to confirm that specific video segments were actually displayed by the electronic display.

### CROSS-REFERENCE TO RELATED APPLICATIONS

This application is a non-provisional patent application of U.S. Applications No. 61/152,876 filed on Feb. 16, 2009 and is herein incorporated by reference in its entirety.

### TECHNICAL FIELD

Exemplary embodiments generally relate to a color light sensor placed in front of an electronic display to monitor actual display performance.

### BACKGROUND OF THE ART

Electronic displays have previously been used predominantly in indoor entertainment applications such as home theatres and bars/restaurants. However, as the performance characteristics and popularity have grown, electronic displays are now being used in many new environments for both entertainment as well as informational and advertising purposes. Displays are now used in airports, shopping malls, sides of buildings, arenas/stadiums, menu boards, and as advertising signs and/or billboards. Exemplary displays are also used for both indoor and outdoor environments.

Over many hours of use, even the most reliable electronic displays are know to degrade in performance or possibly have one or more components fail prematurely. When a display is used for advertising purposes, a sudden failure or degradation in performance can result in the loss of critical advertising exposure and possible revenue to the advertising firm. Further, when a display is used for information, a failure of the display may result in the loss of critical information such as flight schedules or emergency alerts. Also, in some applications a display is required to maintain a certain level of performance (ex. gamma saturation, contrast, luminance, color saturation, etc.). A user may want to monitor the various parameters of the display to determine when the display may begin to degrade in performance. Still further, in some applications there may be several displays used closely with one another (sometimes as an array of displays). In these types of applications it may be preferable to have each display maintain similar performance characteristics, so that the displays appear uniform when viewed as a whole.

### SUMMARY OF THE EXEMPLARY EMBODIMENTS

Exemplary embodiments display a watermark and measure various characteristics of the watermark through one or more color light sensors which are embedded within the display. The color light sensor provides feedback data regarding any number of performance characteristics of the display. The data may be stored internally within the display for later access by the user or may be streamed out of the display in real time to a remote storage device. The data can be used to indicate failures in some of the display componentry or the transmission of the video/audio signals and can also provide input as to the actual performance of the display. Some end-users require specific performance characteristics of their displays and embodiments help to collect the data which can determine whether the displays are meeting the required characteristics. The data can be plotted and analyzed in a number of ways to evaluate the performance of the display.

The foregoing and other features and advantages will be apparent from the following more detailed description of the particular embodiments of the invention, as illustrated in the accompanying drawings.

### BRIEF DESCRIPTION OF THE DRAWINGS

A better understanding of an exemplary embodiment will be obtained from a reading of the following detailed description and the accompanying drawings wherein identical reference characters refer to identical parts and in which:

FIG. 1 is a schematic view of the electrical connections for an exemplary embodiment.

FIG. 2 is a front planar view showing the placement of the sensor in the corner of the active portion of a display.

FIG. 3A is a front planar view showing another embodiment for the placement of the sensor where the sensor is placed behind a surrounding frame.

FIG. 3B is a cross-sectional view showing the section along line 3B-3B in FIG. 3A.

FIG. 4 is a schematic for sending video content to a display.

FIG. 5 is a schematic for sending video content to multiple displays.

### DETAILED DESCRIPTION

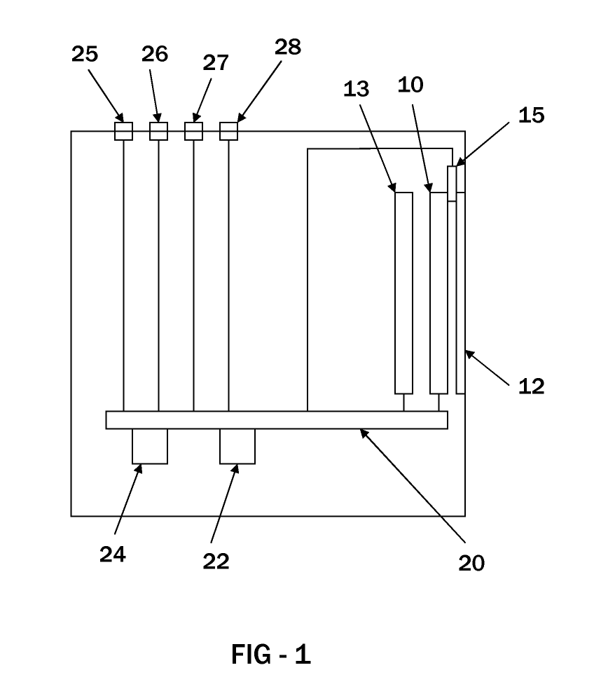

FIG. 1 shows an electrical schematic for a display which contains an embodiment of the display performance monitoring system. A color light sensor 15 may be placed in front of the display assembly 10. In this embodiment, the color light sensor 15 is placed between the display assembly 10 and a front display plate 12 which may protect the display or provide additional optical properties (anti-reflection, polarization, optical matching, light absorption, etc.). The specific embodiment shown here could be used with an LCD display, where the display assembly 10 may be an LCD stack with an associated backlight assembly 13 placed behind the LCD stack. Obviously, with other embodiments using other types of display assemblies, a backlight assembly 13 may not be necessary. Most notably, if using plasma, organic LED, light-emitting polymer, field emission display, and organic electro luminescence technology as the display assembly 10.

The display assembly 10, color light sensor 15, and backlight assembly 13 (if necessary) may be connected to the backplane 20 which can provide communication between the various components of the display. One or more power modules 22 and a display controller assembly 24 may also be in electrical communication with the backplane 20. The display controller assembly 24 may include several different components including, but not limited to a video receiving unit, decompressor, timing and control board (TCON), and display interface board (DIB).

The display may contain several inputs and output interfaces. A video input 25 accepts the video data from a video source and may connect to the backplane 20 or may connect directly to the display controller assembly 24. An RS232 interface 26 as well as an Ethernet/network interface 27 may be used to provide communication between the various display components and the user. The RS232 interface 26 may use standard levels and signals to allow connection to a personal computer. The Ethernet/network interface 27 may provide automatic sensing to allow connection directly to a PC or network hub. Through one or both of these interfaces 26 and 27, the user can monitor the display's performance and change various display settings. A power input 28 can provide power to the display components. Of course, some embodiments may use a different combination of input and output interfaces. For example, some embodiments may use a single interface for both receiving video/audio data as well as communicating display data back to the user. In an exemplary embodiment, this would be a two-way wireless connection or wireless network card. Other embodiments may simply use a single video input 25 with a single Ethernet/network interface 27 without using the RS232 interface 26. The number and style of input and output connections can vary depending on the particular application and would not be outside the scope of the exemplary embodiments.

The watermark may be generated by one or more components of the display controller assembly 24. The watermark is a grouping of image-producing elements (sometimes pixels) on the display assembly 10 which are selected to display a set pattern of colors for measurement by the color light sensor 15. The watermark could be placed anywhere on the display, but since the color light sensor 15 should preferably be placed in front of the viewable area of the display assembly 10, the watermark should preferably be placed in a corner or near the edge of the display assembly 10 so that the image is only disrupted a minimal amount. (The placement of the watermark on the display is discussed further below). In some embodiments, the watermark may simply comprise squares/rectangles (or any other shape) of colors (ex. Red (R), Green (G), Blue (B), or White (W)). The watermark may show each color for a predetermined amount of time while its properties are measured by the color light sensor 15. For example, the watermark may cycle through squares of the following colors in the following times: T1=R, T2=G, T3=B, T4=W, T5=R, etc.

In one embodiment, when the display is initially installed it may be inspected to determine that it is operating properly. Then, once the watermark begins to be displayed, the measurements of the color light sensor may be stored as the reference points for comparison throughout the life of the display. Once the color light sensor determines that the measurements have fallen outside of an acceptable range, this may be indicated to the user and the display may need certain parameters reset or may possibly need serviced and/or replaced. In other embodiments, the required measurement values from the color light sensor may be pre-determined and stored within the display controller assembly. Then during the life of the display, the measurements from the sensor are compared with these pre-determined values and when they fall outside the acceptable range, an error will be reported to the user.

Some embodiments may not report errors out to the user immediately, but instead may simply store the data internally for later retrieval by the user. In an exemplary embodiment, the performance data may be accessed by the user through a web browser. Once the data is retrieved and analyzed it may be determined that the display has malfunctioned and may continue to malfunction and possibly needs servicing or replaced.

Exemplary embodiments provide constant feedback on the performance of the display and can quickly notify the user that the display is not functioning properly. Notifications may be sent to the user's computer, cell phone, or smart device through any of the output data interfaces. A variety of internet notifications could be sent to the user through the Ethernet/network interface 27. Notifications could include email, instant messaging, text messaging, or a web page which can be accessed by the user and may contain the data for a number of different displays. Prior to the exemplary embodiments herein, a user would have no notice of a malfunctioning display unless actually observed by the user. The display may have been malfunctioning for some time before the user actually notices the failure. In some situations, actual observation may be difficult since some display parameters are difficult or impossible to notice with the naked eye. Further, in some applications there may be many displays installed and it may be very difficult to constantly monitor each displays performance. This exemplary embodiments allow constant monitoring from a remote location.

The display controller assembly 24 may generate and display the same watermark regardless of the video which is being displayed. This style may be adopted when the display performance parameters are the only main concern to the user. Alternatively, each video stream may include its own specific watermark. This method would be advantageous if the user desired to measure the precise amount of time that each video is being displayed and confirming that the video was actually shown on a particular display. This would allow an advertising firm to determine exactly how long each client's advertisements were shown and on which specific displays. This can be advantageous when many different displays are being used to advertise for many different clients. This would also permit very precise and accurate billing to the clients of the advertising firm. As mentioned above, advertising prices could vary depending on location of the display, time of day shown, and the number of times the ad was shown.

The embodiments herein allow for a near instantaneous detection of failures in communication between display components, including but not limited to the TCON, DIB, display assembly, all of the cabling/connections in between, as well as the video/audio signal transmitting and receiving devices. In addition to the monitoring of the display components for proper operation, a number of different display parameters can be monitored by the embodiments described herein, including but not limited to: gamma saturation, contrast, luminance, and color saturation.

As an advanced embodiment of the setup described herein, each bit level for each color may be measured to determine if it is working properly. For example, with a typical LCD display, the luminance level for each subpixel (red, green, and blue) may be defined by 8 bits (or whatever bit level is used for the particular display). Thus, each subpixel can vary from Gamma 0 (black) to Gamma 255 (full on). To test the red subpixels for this example, the bits can vary from: 00000000 (black), 00000001, 00000010, 00000100, 00001000, 00010000, 00100000, 01000000, 10000000, 11111111 (full on). By driving the red subpixels at each bit variation and measuring the output by the sensor, it can be determined if each bit level is functioning properly. Obviously, this can be repeated for the green and blue subpixels. Thus, in this embodiment the user can drive the display to show a different watermark strictly for the purpose of evaluating a very specific attribute of the display. A plurality of different watermarks can be developed in order to test a number of corresponding display properties. The ‘testing’ and evaluating of the displays can all take place from a remote location. This allows a user to diagnose and possibly fix problems from remote locations.

Many types of color light sensors would work with the embodiments described herein. An exemplary color light sensor is the TCS3404CS or TCS3414CS which are commercially available from Texas Advanced Optoelectronic Solutions® (TAOS) of Plano, Tex. www.taosinc.com. The TAOS specification document TAOS068 entitled TCS3404CS, TCS3414CS Digital Color Light Sensors' is herein incorporated by reference in its entirety. Any light sensor which is capable of measuring any one of the following properties would work with the embodiments herein: gamma saturation, contrast, luminance, color saturation

Various display types can be used with the embodiments described herein, including but not limited to LCD, plasma, LED, organic LED, light-emitting polymer, field emission display, and organic electro luminescence. As discussed above, some of these displays may not require a backlight assembly. Embodiments may even be used with displays of other types including those not yet discovered.

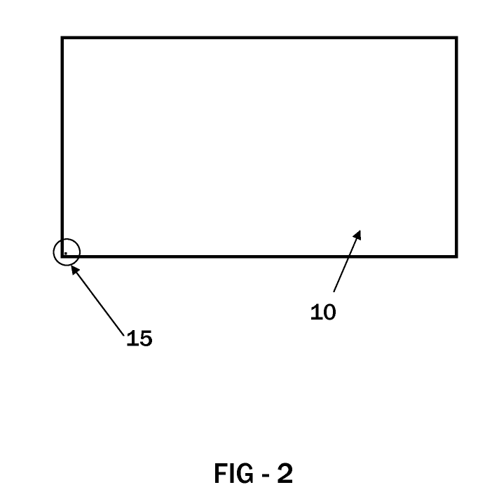

FIG. 2 shows one embodiment for placing the color light sensor 15. Here, the sensor 15 is placed in front of active portions of the display assembly 10. The sensor 15 may or may not be placed behind a front display plate. One disadvantage of this setup is that the sensor 15 may be noticeable by an observer. However, to minimize this effect, the sensor 15 should be as small as possible and should be placed as close to a corner of the display as possible.

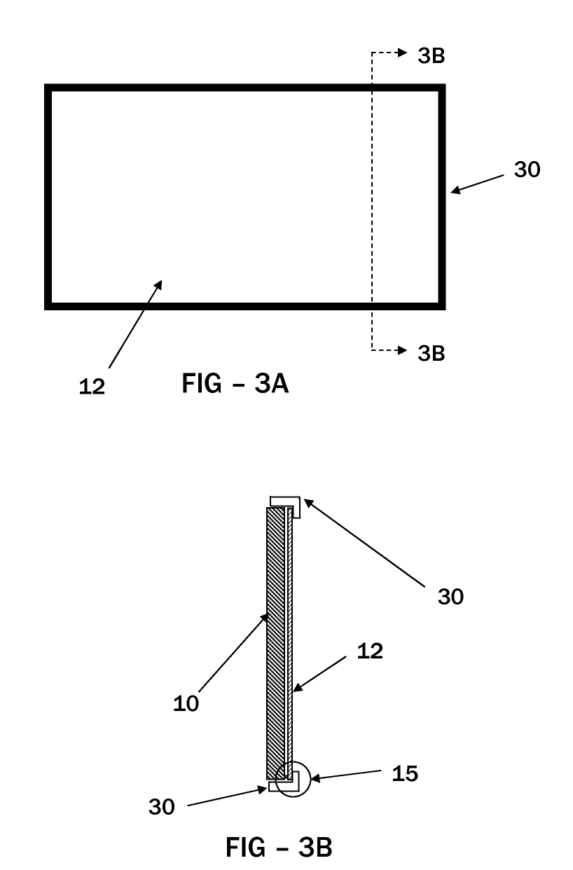

FIG. 3A shows another embodiment for the placing of the color light sensor 15. In this embodiment, a frame 30 is used to surround the display assembly and the front display plate 12. The frame 30 may provide a watertight seal with the front display plate 12. A cross-sectional cut is shown as line 3B-3B and the sectional view is shown in FIG. 3B. The color light sensor 15 may be placed between the front display plate 12 and the display assembly 10. In this embodiment, the color light sensor 15 may be placed behind the frame 30 so that it cannot be seen by an observer. The disadvantage to this embodiment is that some of the active portions of the display will be covered by the frame 30. Again, to minimize this effect, the frame 30 should cover the smallest amount of the active display as possible.

Obviously, one of ordinary skill in the art can place the sensor in a number of different places to provide the same affect. As mentioned above, multiple sensors could be also be used to provide additional measurements, or perhaps measure different watermarks simultaneously.

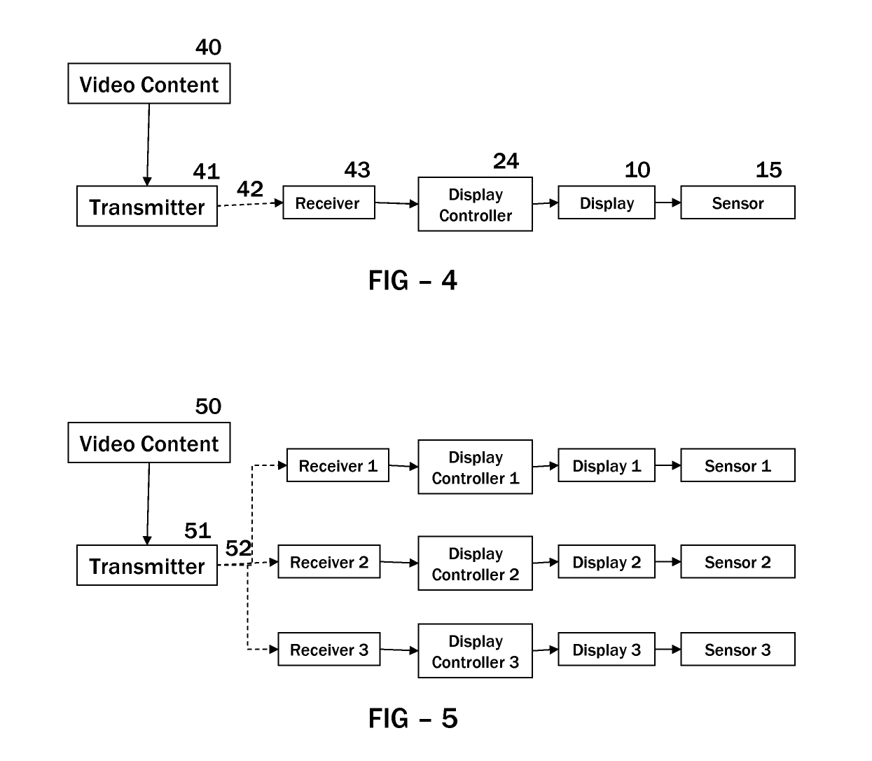

FIG. 4 shows the schematic for one embodiment for sending video (and sometimes audio) signals to the display. In this embodiment, the video content 40 is sent to a transmitting device 41 which may encode or compress the video content 40 prior to transmitting it (if necessary). A receiving device 43 receives the video (and sometimes audio) content 40 through a wired or wireless connection 42. The receiving device 43 may be a separate component or may be incorporated into the display controller assembly 24. Either the receiving device 43 or the display controller assembly 24 may decode and/or decompress (if necessary) the video content 40. The display controller 24 may then insert the watermark into the controller data and send this to the display assembly 10. The color light sensor 15 then analyzes the watermark and returns data covering various attributes of the watermark and thus the display itself. For simplicity, the returning electrical signals from the sensor 15 are not shown. As discussed above, these signals (data) can be sent to the user in a number of ways. Further, the transmitter 41 and receiver 43 may be in two-way communication with one another where both may transmit and receive data such that they are not strictly a ‘transmitter’ or ‘receiver’ but are in fact transmitting/receiving devices.

As can be observed even with this simplification of the process, there are several connections and many components involved in the transfer of video content 40 to the display assembly 10. With these connections and components comes the opportunity for failure or degradation which was previously undetected unless actually observed by the user.

FIG. 5 shows another schematic where a transmitter 51 sends video content 50 to several displays over a wired or wireless connection 52. This embodiment shows the importance in being able to determine if video was actually properly transmitted to a display and then ultimately shown on the screen. There are several components that must work in harmony and a failure can result in loss of video to some or all of the displays. Further, other wireless systems or electromagnetic interference can also prevent some displays from receiving the video signals and displaying them properly. It is important that some advertising companies can actually confirm that certain portions of video were actually shown on a specific number of displays. The embodiments herein allow them to carefully track which video segments were shown, how long, and precisely on which displays. Advertisers may even charge a different rate for each display (depending on its location). Specifically, the addition of a watermark (possibly unique for each customer) to each customer's video segment allows the measurement and detection of specific portions of video.

Further, it may be desirable to use several displays closely together sometimes in an array. This may be done in order to approximate a much larger display which may be impractical to build and/or install. Thus, a user can purchase several smaller displays and place them adjacent to one another to create a larger display. In these instances it may be desirable for each display to maintain similar optical properties so that differences between the displays are not noticeable and the displays appear as one. Thus, the embodiments of the display performance monitoring system can be used to ensure that each display maintains similar optical properties (ex. gamma saturation, contrast, luminance, color saturation, etc.). In some embodiments, it may be desirable to place a color light sensor along each edge of a display which is adjacent to the edge of another display. In this way, the optical properties along each ‘boundary edge’ can be controlled to minimize the visible difference between adjacent displays.

It has been found, that in some applications where the display is used in an outdoor and/or bright ambient environment, the ambient light may reflect off the display assembly and enter the color light sensor. In these applications, the color light sensor may become oversaturated with light so that it may not be able to accurately read the optical performance of the display assembly. In these situations it has been found that placing a filter between the color light sensor and the display assembly may alleviate some or all of these problems. An exemplary embodiment may use a ‘hot mirror’ type IR filter. Some embodiments may use any type of filter that removes or reduces electromagnetic radiation having wavelengths longer than 600-650 nanometers.

Having shown and described preferred embodiments, those skilled in the art will realize that many variations and modifications may be made to affect the described embodiments and still be within the scope of the claimed invention. Additionally, many of the elements indicated above may be altered or replaced by different elements which will provide the same result and fall within the spirit of the claimed invention. It is the intention, therefore, to limit the invention only as indicated by the scope of the claims.

1. A performance monitoring system for an electronic display comprising:
an electronic display assembly;
a color light sensor placed in front of the electronic display assembly; and
a network connection in electrical communication with the color light sensor.

2. The system of claim 1 wherein:
the network connection is in electrical communication with the internet.

3. The system of claim 1 further comprising:
a video transmitter in electrical communication with the electronic display assembly.

4. The system of claim 1 further comprising:
a grouping of image-producing elements on the front of the display assembly which are measured by the color light sensor.

5. The system of claim 1 further comprising:
a hot mirror filter placed between the color light sensor and the display assembly.

6. The system of claim 1 wherein:
the electronic display assembly is a liquid crystal display.

7. The system of claim 1 wherein:
the electronic display assembly is an OLED display.

8. A performance monitoring system for an electronic display comprising:
an electrical backplane;
a display controller assembly in electrical communication with the backplane;
an electronic display assembly in electrical communication with the display controller assembly, the electronic display assembly having a plurality of image producing elements;
a color light sensor placed in front of the electronic display assembly and in electrical communication with the backplane;
a video input in electrical communication with the display controller assembly; and
a network interface in electrical communication with the backplane.

9. The system of claim 8 further comprising:
protective glass placed in front of the color light sensor.

10. The system of claim 8 further comprising:
a grouping of image-producing elements on the front of the display assembly which are measured by the color light sensor.

11. The system of claim 8 wherein:
the network interface is in electrical communication with the internet.

12. The system of claim 8 further comprising:
a hot mirror filter placed between the color light sensor and the display assembly.

13. The system of claim 8 further comprising:
a user interface in electrical communication with the network interface.

14. The system of claim 13 wherein:
the user interface is a web browser.

15. The system of claim 8 wherein:
the electronic display assembly is a liquid crystal display.

16. The system of claim 8 wherein:
the electronic display assembly is an OLED display.

17. A method for monitoring the optical properties of an electronic display comprising the steps of:
presenting an electronic display having a plurality of image-producing elements with a color light sensor placed in front of a grouping of image-producing elements;
displaying an image on the grouping of image-producing elements;
measuring an optical property of the image to produce optical data;
transmitting the optical data to a user.

18. The method of claim 17 wherein:
the displaying step comprises displaying a series of solid-colored shapes.

19. The method of claim 17 wherein the transmitting step further comprises:
establishing a network connection with the color light sensor;
providing the user with a web application capable of electrically communicating with the network connection;
allowing the user to receive optical data through the web application.

20. The method of claim 17 wherein:
the optical data is any one of the following: luminance, color saturation, and contrast.

21. The method of claim 17 further comprising the steps of:
selecting a range of acceptable values for the optical data;
comparing the optical data with the range of acceptable values;
notifying the user when optical data falls outside of the range of acceptable values.

22. The method of claim 21 wherein:
the notifying step comprises sending the user an email.

23. The method of claim 21 wherein:
the notifying step comprises sending the user a text message.

24. A method for remotely monitoring and transmitting the optical properties of an electronic display to a user, the method comprising the steps of:
presenting an electronic display having a plurality of pixels and four edges;
selecting a group of pixels near one edge of the display as a watermark;
placing a color light sensor in front of the watermark;
displaying a test image with the watermark;
measuring an optical property of the test image to produce optical data;
storing the optical data at the electronic display with a storage device; and
establishing a network connection with the storage device.

25. The method of claim 24 further comprising the steps of:
providing the user with a web application capable of electrically communicating with the network connection; and
allowing the user to receive optical data from the storage device through the web application.

26. The method of claim 24 further comprising the steps of:
selecting a range of acceptable values for the optical data;
comparing the optical data with the range of acceptable values;
notifying the user when optical data falls outside of the range of acceptable values.

27. The method of claim 24 wherein:
the test image is a solid-colored shape.

28. The method of claim 24 wherein:
the optical data is any one of the following: luminance, color saturation, and contrast.
